(19) United States
(12) Patent Application Publication
(10) Pub. No.: US 2019/0019706 A1
(43) Pub. Date: Jan. 17, 2019

(54) SUBSTRATE PROCESSING DEVICE

(71) Applicant: SCREEN Holdings Co., Ltd., Kyoto (JP)

(72) Inventors: Manabu TAKUSARI, Kyoto (JP); Ryo MURAMOTO, Kyoto (JP)

(21) Appl. No.: 16/068,685

(22) PCT Filed: Mar. 16, 2017
(86) PCT No.: PCT/JP2017/010770

§ 371 Date: Jul. 9, 2018

(30) Foreign Application Priority Data
Mar. 30, 2016 (JP) 2016-067178

(51) Int. Cl. H01L 21/677; H01L 21/67

(52) U.S. Cl. CPC H01L 21/67706; H01L 21/67173

(57) ABSTRACT

A substrate processing apparatus has an inner region surrounded by an outer wall, and the inner region is divided by a first partition wall into first and second substrate transfer regions. The substrate processing apparatus is provided with first and second substrate transfer robots which are arranged respectively at the first and second substrate transfer regions, a processing unit which is disposed adjacent to the second substrate transfer region, a control portion which controls motions of the first and second substrate transfer robots, a selective power supply turn-on means which selectively turns on the second substrate transfer robot while turning off the first substrate transfer robot, a controller which inputs into the control portion an adjustment signal for adjusting motions of the second substrate transfer robot, and an interlock means which individually detects the entry of a person into each of the first and second substrate transfer regions and turns off a substrate transfer robot at a corresponding region.

### FIELD OF THE INVENTION

The present invention relates to a substrate processing apparatus which gives various types of processing to a substrate.

### DESCRIPTION OF THE RELATED ART

A substrate processing apparatus has been conventionally used for giving various types of processing to substrates such as conductor substrates, substrates for liquid crystal displays, substrates for plasma displays, substrates for FEDs (Field Emission Displays), substrates for optical disks, substrates for magnetic disks, substrates for magneto-optical disks and substrates for photomasks. For example, in a process for manufacturing semiconductor apparatuses, there has been used a substrate processing apparatus which is provided with processing units for carrying out a series of processing steps and which is improved in production efficiency by integrating the plurality of processing units.

Such a substrate processing apparatus is provided with a cassette placement portion on which a cassette for housing an unprocessed substrate is placed, a plurality of processing units which give substrate processing such as cleaning to the unprocessed substrate which has been taken out from the cassette, and a substrate transfer robot which automatically transfers the unprocessed substrate inside the cassette to a desired processing unit.

The substrate processing apparatus is provided with a door which allows an operator to enter into the substrate processing apparatus and perform maintenance work on the processing units and the substrate transfer robot, etc. (refer to Patent Document 1).

### PRIOR ART DOCUMENT

### Patent Document

Patent Document 1: Japanese Patent Application Publication No. 2005-175125

### SUMMARY OF THE INVENTION

### Technical Problem

An object of the present invention is to provide a substrate processing apparatus in which maintenance work can be performed safely even where an operator opens a door provided on the apparatus and enters into the apparatus.

### Solution to Problems

One preferred embodiment of the present invention provides a substrate processing apparatus in which an inner region surrounded by an outer wall is divided by a first partition wall into two substrate transfer regions (first and second substrate transfer regions). The substrate processing apparatus is provided with substrate transfer robots (first and second substrate transfer robots) which are arranged respectively at the first and second substrate transfer regions, a processing unit which is disposed adjacent to the second substrate transfer region in order to give predetermined substrate processing to a substrate, a control portion which controls motions of the first and the second substrate transfer robot, a selective power supply turn-on means which selectively turns on the second substrate transfer robot, while turning off the first substrate transfer robot, a controller which inputs into the control portion an adjustment signal for adjusting motions of the second substrate transfer robot, and an interlock means which detects individually the entry of a person into each of the first and second substrate transfer regions and turns off a substrate transfer robot at a corresponding region. A first observation region for observing macroscopically the second substrate transfer region from the first substrate transfer region is formed at the first partition wall. The outer wall is provided with a first door which leads to the first substrate transfer region. The first substrate transfer robot delivers and receives a substrate to and from the second substrate transfer robot. The second substrate transfer robot delivers and receives a substrate to and from the first substrate transfer robot and also delivers and receives a substrate to and from the processing unit. At the first substrate transfer region, there is set a first work position at which an operator who has reached the first substrate transfer region through the first door observes macroscopically the second substrate transfer robot through the first observation region and adjusts motions of the second substrate transfer robot via the controller.

According to the substrate processing apparatus of the present preferred embodiment, an operator turns on the second substrate transfer robot by using the selective power supply turn-on means, with the first substrate transfer robot kept turned off . Thereby, the operator is able to enter safely into the first substrate transfer region from the first door. Since the interlock means is actuated at each region, the second substrate transfer robot is not turned off in response to the entry of the operator.

Thereafter, the operator observes macroscopically the second substrate transfer robot through the first observation region and adjusts the second substrate transfer robot by inputting an adjustment signal via the controller.

The first partition wall is provided with the first observation region and, therefore, the operator is able to adjust the second substrate transfer robot safely in a state of being isolated from the second substrate transfer robot by the first partition wall.

Even if a person enters into the second substrate transfer region during the adjustment work, the interlock means detects the entry of the person and turns off a robot at a corresponding region, that is, the second substrate transfer robot, thereby preventing interference of the person with the second substrate transfer robot.

One preferred embodiment of the present invention provides a substrate processing apparatus in which an inner region surrounded by an outer wall is divided by first and second partition walls into three substrate transfer regions (first, second and third substrate transfer regions). The substrate processing apparatus is provided with substrate transfer robots (first, second and third substrate transfer robots) arranged respectively at the first, second and third substrate transfer regions, a processing unit which is disposed adjacent to the third substrate transfer region in order to give predetermined substrate processing to a substrate, a control portion which controls motions of the first, second and third substrate transfer robots, a selective power supply turn-on means which selectively turns on the second substrate transfer robot, while turning off the first and third substrate transfer robots, a controller which inputs into the control portion an adjustment signal for adjusting motions of the second substrate transfer robot, and an interlock means which detects individually the entry of a person into each of the first, second and third substrate transfer regions and turns off a substrate transfer robot at a corresponding region. A first observation region for observing macroscopically the second substrate transfer region from the first substrate transfer region is formed at the first partition wall. The outer wall is provided with a first door which leads to the first substrate transfer region. The first substrate transfer robot delivers and receives a substrate to and from the second substrate transfer robot. The second substrate transfer robot delivers and receives a substrate to and from the first substrate transfer robot and also delivers and receives a substrate to and from the third substrate transfer robot. The third substrate transfer robot delivers and receives a substrate to and from the second substrate transfer robot and also delivers and receives a substrate to and from the processing unit. At the first substrate transfer region, there is set a first work position at which an operator who has reached the first substrate transfer region through the first door observes macroscopically the second substrate transfer robot through the first observation region and adjusts motions of the second substrate transfer robot via the controller.

According to the substrate processing apparatus of the present preferred embodiment, an operator turns on the second substrate transfer robot by using the selective power supply turn-on means, with the first and third substrate transfer robots kept turned off. Thereby, the operator is able to enter safely into the first substrate transfer region from the first door. Since the interlock means is actuated at each region, the second substrate transfer robot is not turned off in response to the entry of the operator.

Thereafter, the operator observes macroscopically the second substrate transfer robot through the first observation region and inputs an adjustment signal via the controller to adjust the second substrate transfer robot. The first partition wall is provided with the first observation region. Therefore, the operator is able to adjust the first substrate transfer robot safely in a state of being isolated from the second substrate transfer robot by the first partition wall.

Even if a person enters into the second substrate transfer region during the adjustment work, the interlock means detects the entry of the person and turns off a robot at a corresponding region, that is, the second substrate transfer robot, thereby preventing interference of the person with the second substrate transfer robot.

One preferred embodiment of the present invention provides a substrate processing apparatus in which an inner region surrounded by an outer wall is divided by a first partition wall into two substrate transfer regions (first and second substrate transfer regions). The substrate processing apparatus is provided with substrate transfer robots (first and second substrate transfer robots) arranged respectively at the first and second substrate transfer regions, a processing unit which is disposed adjacent to the second substrate transfer region in order to give predetermined substrate processing to a substrate, a control portion which controls motions of the first and second substrate transfer robots, a selective power supply turn-on means which selectively turns on the first substrate transfer robot, while turning off the second substrate transfer robot, a controller which inputs into the control portion an adjustment signal for adjusting motions of the first substrate transfer robot, and an interlock means which detects individually the entry of a person into each of the first and second substrate transfer regions and turns off a substrate transfer robot at a corresponding region. A first observation region for observing macroscopically the first substrate transfer region from the second substrate transfer region is formed at the first partition wall. The outer wall is provided with a second door which leads to the second substrate transfer region. The first substrate transfer robot delivers and receives a substrate to and from the second substrate transfer robot. The second substrate transfer robot delivers and receives a substrate to and from the first substrate transfer robot and also delivers and receives a substrate to and from the processing unit. At the second substrate transfer region, there is set a second work position at which an operator who has reached the second substrate transfer region through the second door observes macroscopically the first substrate transfer robot through the first observation region and adjusts motions of the first substrate transfer robot via the controller.

According to the substrate processing apparatus of the present preferred embodiment, an operator turns on the first substrate transfer robot by using the selective power supply turn-on means, with the second substrate transfer robot kept turned off. Thereby, the operator is able to enter safely into the second substrate transfer region from the second door. Since the interlock means is actuated at each region, the first substrate transfer robot is not turned off in response to the entry of the operator.

Thereafter, the operator observes macroscopically the first substrate transfer robot through the first observation region and adjusts the first substrate transfer robot by inputting an adjustment signal via the controller. The first partition wall is provided with the first observation region. Therefore, the operator is able to adjust the first substrate transfer robot safely in a state of being isolated from the first substrate transfer robot by the first partition wall.

Even if a person enters into the first substrate transfer region during the adjustment work, the interlock means detects the entry of the person and turns off a robot at a corresponding region, that is, the first substrate transfer robot, thereby preventing interference of the person with the first substrate transfer robot.

One preferred embodiment of the present invention provides a substrate processing apparatus in which an inner region surrounded by an outer wall is divided by a first partition wall and a second partition wall into three substrate transfer regions (first, second and third substrate transfer regions). The substrate processing apparatus is provided with substrate transfer robots (first, second and third substrate transfer robots) which are arranged respectively at the first, second and third substrate transfer regions, a processing unit which is disposed adjacent to the third substrate transfer region in order to give predetermined substrate processing to a substrate, a control portion which controls motions of the first, second and third substrate transfer robots, a selective power supply turn-on means which selectively turns on the first substrate transfer robot, while turning off the second and third substrate transfer robots, a controller which inputs into the control portion an adjustment signal for adjusting motions of the first substrate transfer robot, and an interlock means which detects individually the entry of a person into each of the first to third substrate transfer regions to stop motions of a substrate transfer robot at a corresponding region. A first observation region for observing macroscopically the first substrate transfer region from the second substrate transfer region is formed at the first partition wall. The outer wall is provided with a second door which leads to the third substrate transfer region. The second partition wall is provided with a third door which leads to the second substrate transfer region from the third substrate transfer region. The first substrate transfer robot delivers and receives a substrate to and from the second substrate transfer robot. The second substrate transfer robot delivers and receives a substrate to and from the third substrate transfer robot. The third substrate transfer robot delivers and receives a substrate to and from the second substrate transfer robot and also delivers and receives a substrate to and from the processing unit at the third substrate transfer region. At the second substrate transfer region, there is set a second work position at which an operator who has reached the second substrate transfer region through the second and the third door observes macroscopically the first substrate transfer robot through the first observation region and adjusts motions of the first substrate transfer robot via the controller.

According to the substrate processing apparatus of the present preferred embodiment, an operator turns on the first substrate transfer robot by using the selective power supply turn-on means, with the second and third substrate transfer robots kept turned off. Thereby, the operator is able to move safely to the third substrate transfer region from the second door and to the second substrate transfer region from the third door. Since the interlock means is actuated at each region, the first substrate transfer robot is not turned off in response to the entry of the operator.

Thereafter, the operator observes macroscopically the first substrate transfer robot through the first observation region and adjusts the first substrate transfer robot by inputting an adjustment signal via the controller. The first partition wall is provided with the first observation region. Therefore, the operator is able to adjust safely the first substrate transfer robot in a state of being isolated from the first substrate transfer robot by the first partition wall.

Even if a person enters into the first substrate transfer region during the adjustment work, the interlock means detects the entry of the person and turns off a robot at a corresponding region, that is, the first substrate transfer robot, thereby preventing interference of the person with the first substrate transfer robot.

In one preferred embodiment of the present invention, the first partition wall is provided with a one-way door that opens in a direction from the first substrate transfer region to the second substrate transfer region but does not open in a reverse direction.

In one preferred embodiment of the present invention, the first substrate placement portion for placing a substrate when delivering the substrate between the first substrate transfer robot and the second substrate transfer robot is provided so as to penetrate through the first partition wall. In the present preferred embodiment, the first observation region is set inside the first substrate placement portion.

In the substrate processing apparatus of the present preferred embodiment, the first observation region is formed inside the first substrate placement portion, thereby eliminating a necessity for installing at the first partition wall the first observation region which is different from a region at which a substrate is delivered from the first substrate transfer robot to the second substrate transfer robot.

One preferred embodiment of the present invention provides a substrate processing apparatus in which an inner region surrounded by an outer wall is divided by a first partition wall and a second partition wall into three substrate transfer regions (first, second and third substrate transfer regions). The substrate processing apparatus is provided with substrate transfer robots (first, second and third substrate transfer robots) which are arranged respectively at the first, the second and the third substrate transfer region, a processing unit which is disposed adjacent to the third substrate transfer region in order to give predetermined substrate processing to a substrate, a control portion which controls motions of the first, second and third substrate transfer robots, a selective power supply turn-on means which selectively turns on the third substrate transfer robot while turning off the first and second substrate transfer robots, a controller which inputs into the control portion an adjustment signal for adjusting motions of the third substrate transfer robot, and an interlock means which individually detects the entry of a person into each of the first, second and third substrate transfer regions and turns off a substrate transfer robot at a corresponding region. A second observation region for observing macroscopically the third substrate transfer region through the second substrate transfer region is formed at the second partition wall. The outer wall is provided with a first door which leads to the first substrate transfer region. The first partition wall is provided with a fourth door which leads to the second substrate transfer region through the first substrate transfer region. The first substrate transfer robot delivers and receives a substrate to and from the second substrate transfer robot. The second substrate transfer robot delivers and receives a substrate to and from the first substrate transfer robot and also delivers and receives a substrate to and from the third substrate transfer robot. The third substrate transfer robot delivers and receives a substrate to and from the second substrate transfer robot and also delivers and receives a substrate to and from the processing unit. At the second substrate transfer region, there is set a third work position at which an operator who has reached the second substrate transfer region through the first door and the fourth door observes macroscopically the third substrate transfer robot through the second observation region and adjusts motions of the third substrate transfer robot via the controller.

According to the substrate processing apparatus of the present preferred embodiment, an operator turns on the third substrate transfer robot by using the selective power supply turn-on means, with the first and second substrate transfer robots kept turned off. Thereby, the operator is able to enter safely into the second substrate transfer region from the first door and the fourth door. Since the interlock means is actuated at each region, the third substrate transfer robot is not turned off in response to the entry of the operator.

Thereafter, the operator observes macroscopically the third substrate transfer robot through the second observation region and adjusts the third substrate transfer robot by inputting an adjustment signal via the controller. The second partition wall is provided with the second observation region and, therefore, the operator is able to adjust safely the third substrate transfer robot in a state of being isolated from the third substrate transfer robot by the second partition wall.

If a person enters into the third substrate transfer region during the adjustment work, the interlock means detects the entry of the person and turns off a robot at a corresponding region, that is, the third substrate transfer robot, thereby preventing interference of the person with the third substrate transfer robot.

In one preferred embodiment of the present invention, the second partition wall is provided with a one-way door that opens in a direction from the third substrate transfer region to the second substrate transfer region but does not open in a reverse direction.

One preferred embodiment of the present invention provides a substrate processing apparatus in which an inner region surrounded by an outer wall is divided by a first partition wall and a second partition wall into three substrate transfer regions (first, second and third substrate transfer regions). The substrate processing apparatus is provided with substrate transfer robots (first, second and third substrate transfer robots) which are arranged respectively at the first, the second and the third substrate transfer region, a processing unit which is disposed adjacent to the third substrate transfer region in order to give predetermined substrate processing to a substrate, a control portion which controls motions of the first, second and third substrate transfer robots, a selective power supply turn-on means which selectively turns on the second substrate transfer robot, while turning off the first and third substrate transfer robots, a controller which inputs into the control portion an adjustment signal for adjusting motions of the second substrate transfer robot, and an interlock means which detects individually the entry of a person into each of the first, second and third substrate transfer regions and turns off a substrate transfer robot at a corresponding region. A second observation region for observing macroscopically the second substrate transfer region from the third substrate transfer region is formed at the second partition wall. The outer wall is provided with a second door which leads to the third substrate transfer region. The first substrate transfer robot delivers and receives a substrate to and from the second substrate transfer robot. The second substrate transfer robot delivers and receives a substrate to and from the second substrate transfer robot and also delivers and receives a substrate to and from the third substrate transfer robot. The third substrate transfer robot delivers and receives a substrate to and from the second substrate transfer robot and also delivers and receives a substrate to and from the processing unit. At the third substrate transfer region, there is set a fourth work position at which an operator who has reached the third substrate transfer region through the second door observes macroscopically the second substrate transfer robot through the second observation region and adjusts motions of the second substrate transfer robot via the controller.

According to the substrate processing apparatus of the present preferred embodiment, an operator turns on the second substrate transfer robot by using the selective power supply turn-on means, with the first and third substrate transfer robots kept turned off. Thereby, the operator is able to enter safely into the third substrate transfer region from the second door. Since the interlock means is actuated at each region, the second substrate transfer robot is not turned off in response to the entry of the operator.

Thereafter, the operator observes macroscopically the second substrate transfer robot through the second observation region and adjusts the second substrate transfer robot by inputting an adjustment signal via the controller. The second partition wall is provided with the second observation region and, therefore, the operator is able to adjust safely the second substrate transfer robot in a state of being isolated from the second substrate transfer robot by the second partition wall.

Even if a person enters into the second substrate transfer region during the adjustment work, the interlock means detects the entry of the person and turns off a robot at a corresponding region, that is, the second substrate transfer robot, thereby preventing interference of the person with the second substrate transfer robot.

In one preferred embodiment of the present invention, a second substrate placement portion for placing a substrate when delivering the substrate between the second substrate transfer robot and the third substrate transfer robot is disposed so as to penetrate through the second partition wall.

In the present preferred embodiment, the second observation region is set inside the second substrate placement portion.

In the substrate processing apparatus of the present preferred embodiment, the second observation region is formed inside the second substrate placement portion, thereby eliminating a necessity for providing at the second partition wall the second observation region which is different from a region at which a substrate is delivered from the second substrate transfer robot to the third substrate transfer robot.

According to a constitution of each of the preferred embodiments, even where a person enters into the apparatus from a door provided on the outer wall of substrate processing apparatus, the person is able to adjust safely the substrate transfer robot.

The above and other objects, features and effects of the present invention will become more apparent from the following description of the preferred embodiments with reference to the accompanying drawings.

### BRIEF DESCRIPTION OF THE DRAWINGS

FIG. 1 is an illustrative plan view which illustrates a layout inside a substrate processing apparatus according to a first preferred embodiment of the present invention.

FIG. 2 is a sectional view of a first partition wall 5.

FIG. 3 is a sectional view of a second partition wall 6.

FIG. 4 is a block diagram which illustrates an electrical configuration of a main portion in the substrate processing apparatus 1.

FIG. 5 is a flowchart which illustrates procedures for teaching by an operator.

FIG. 6 is a plan view of a terminal panel TE1 (terminal panel TE2).

FIG. 7 is a front elevational view of the first partition wall 5 on the side of a first substrate transfer region G1.

FIG. 8 is a front elevational view of the second partition wall 6 on the side of a second substrate transfer region G2.

FIG. 9 is a flowchart for describing a modification example of procedures for teaching by an operator.

FIG. 10 is an illustrative plan view which illustrates a layout inside a substrate processing apparatus according to a second preferred embodiment.

### DETAILED DESCRIPTION OF THE PREFERRED EMBODIMENTS

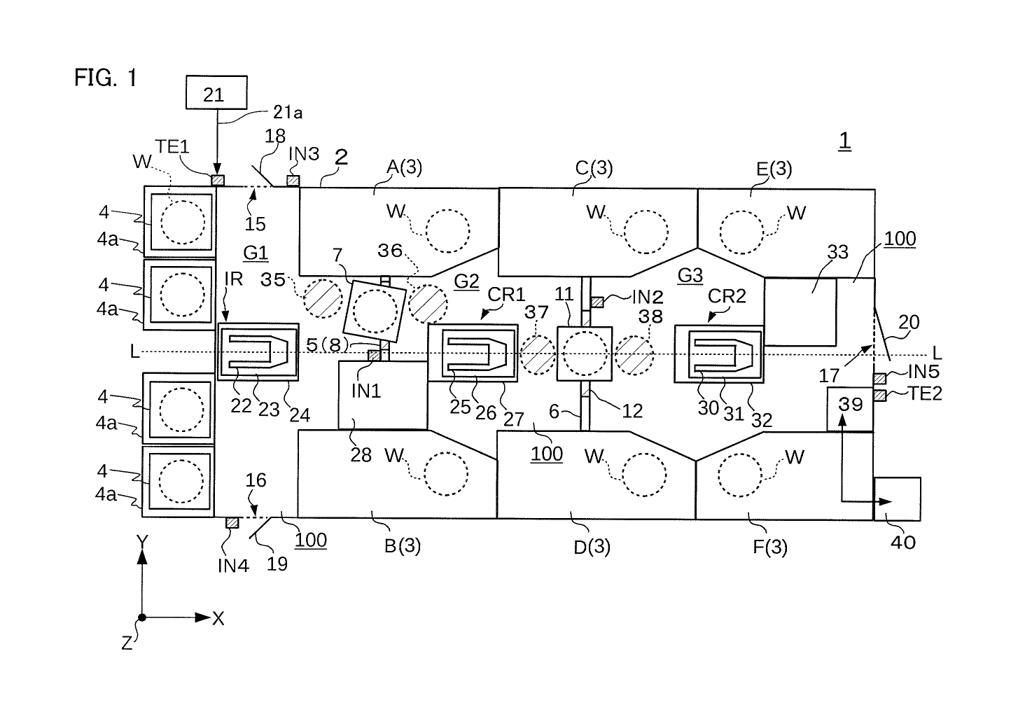

FIG. 1 is an illustrative plan view which illustrates a layout inside the substrate processing apparatus 1 according to the first preferred embodiment of the present invention. The substrate processing apparatus 1 is a single substrate processing type apparatus which gives various types of processing such as washing and etching to substrates W such as semiconductor wafers one by one. As shown in FIG. 1, the substrate processing apparatus 1 has an outer wall 2. An inner region 100 of the apparatus which is surrounded by the outer wall 2 is roughly classified into processing regions A to F for processing substrates W and a transfer region G.

Each of the processing regions A to F is provided with a plurality of processing units 3 (four units in the present preferred embodiment) stacked in a vertical direction for giving specific processing such as cleaning and etching to a substrate W.

An indexer robot IR, a first main robot CR1 and a second main robot CR2 are arranged at the transfer region G. The indexer robot IR delivers a substrate W to a cassette 4 which houses the plurality of substrates W. The first main robot CR1 delivers a substrate W to the indexer robot IR and also delivers a substrate W to the processing units 3 which belong to either of the processing regions A and B. The second main robot CR2 delivers a substrate W to the first main robot CR1 and also delivers a substrate W to the processing units 3 which belong to any of the processing regions C to F.

In the transfer region G, a region at which the indexer robot IR transfers a substrate W is referred to as a first substrate transfer region G1, a region at which the first main robot CR1 transfers a substrate W is referred to as a second substrate transfer region G2, and a region at which the second main robot CR2 transfers a substrate W is referred to as a third substrate transfer region G3. The first substrate transfer region G1, the second substrate transfer region G2 and the third substrate transfer region G3 extend as a whole horizontally in one direction. A direction at which the first substrate transfer region G1, the second substrate transfer region G2 and the third substrate transfer region G3 extend is referred to as an X direction. A direction which is orthogonal to the X direction on a horizontal plane is referred to as a Y direction, and a vertical direction which is orthogonal to the X direction and the Y direction is referred to as a Z direction. A transfer-region center line L to L which passes through the center of each of the first to the third transfer region G1 to G3 in the Y direction is shown in FIG. 1.

A first partition wall 5 is disposed between the first substrate transfer region G1 and the second substrate transfer region G2. Further, a second partition wall 6 is disposed between the second substrate transfer region G2 and the third substrate transfer region G3. Therefore, the inner region 100 of the substrate processing apparatus 1 is divided by the first partition wall 5 and the second partition wall 6 into the first substrate transfer region G1, the second substrate transfer region G2 and the third substrate transfer region G3.

On both sides of the first substrate transfer region G1 along the X direction, the plurality of processing units 3 which belong to either of the processing regions A and B are disposed adjacent to the region G1. Similarly, on both sides of the second substrate transfer region G2 along the X direction, the plurality of processing units 3 which belong to any of the processing regions A, B, C and D are disposed adjacent to the region G2. Similarly, also on both sides of the third substrate transfer region G3 along the X direction, the plurality of processing units 3 which belong to any of the processing regions C, D, E and F are disposed adjacent to the region G3.

The plurality of cassettes 4 are arranged in the Y direction in a state of being placed on a cassette placement portion 4a. A plurality of substrates W are stacked and arranged inside each of the cassettes 4 in a state of being isolated from each other.

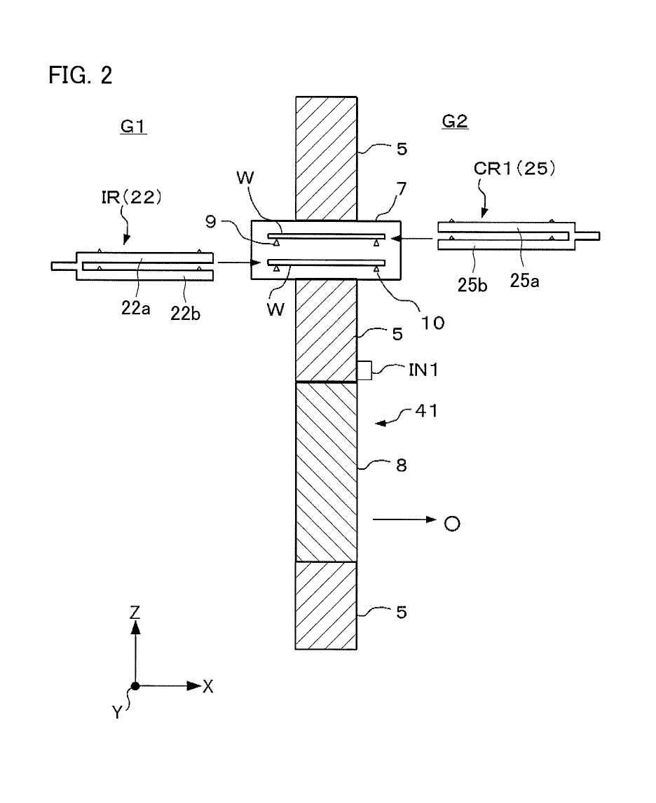

FIG. 2 is a sectional view of the first partition wall 5. As shown in FIG. 2, the first partition wall 5 is provided with a first substrate placement portion 7 for delivering a substrate W between the indexer robot IR and the first main robot CR1 so as to penetrate through the first partition wall 5. The first partition wall 5 is also provided with an opening 41 by which the first substrate transfer region G1 communicates with the second substrate transfer region G2 and a door 8 (fourth door) which opens and closes the opening 41.

Substrate supporting members 9 and 10 are placed in parallel at the first substrate placement portion 7 in the Z direction, and each of the substrate supporting members 9, 10 can support a substrate W one at a time in a horizontal posture, whereby a total of two substrates W can be supported at the same time. The upper substrate supporting member 9 is used when a substrate W is delivered from the first main robot CR1 to the indexer robot IR, while the lower substrate supporting member 10 is used when a substrate W is delivered from the indexer robot IR to the first main robot CR1. FIG. 2 illustratively shows the positions of the indexer robot IR and the first main robot CR1.

The first substrate placement portion 7 is arranged at a position which deviates from the transfer-region center line L to L to the Y direction, when viewed from above (refer to FIG. 1).

The door 8 provided at the first partition wall 5 is a one-way door that opens in a direction from the first substrate transfer region G1 to the second substrate transfer region G2 but does not open in a direction from the second substrate transfer region G2 to the first substrate transfer region G1.

In the vicinity of the door 8 of the first partition wall 5, there is provided an interlock switch IN1 for cutting off power supplies of the substrate transfer robots (the indexer robot IR and the first main robot CR1) positioned at the substrate transfer regions corresponding to the door 8 (that is, the first substrate transfer region G1 and the second substrate transfer region G2) interlocking with opening of the door 8.

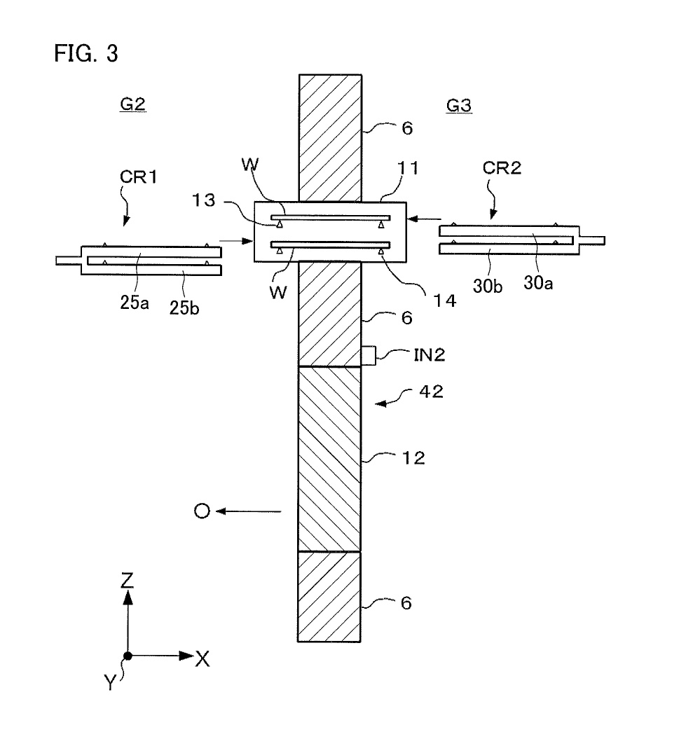

FIG. 3 is a sectional view of the second partition wall 6. As shown in FIG. 3, the second partition wall 6 is provided with a second substrate placement portion 11 for delivering a substrate W between the first main robot CR1 and the second main robot CR2 so as to penetrate through the second partition wall 6. The second partition wall 6 is also provided with an opening 42 by which the second substrate transfer region G2 communicates with the third substrate transfer region G3 and a door 12 (a third door) which opens and closes the opening 42.

Substrate supporting members 13 and 14 are placed in parallel at the second substrate placement portion 11 in the Z direction, and each of the substrate supporting members 13, 14 is able to support a substrate W one at a time in a horizontal posture, whereby a total of two substrates W can be supported at the same time. The upper substrate supporting member 13 is used when a substrate W is delivered from the second main robot CR2 to the first main robot CR1, while the lower substrate supporting member 14 is used when a substrate W is delivered from the first main robot CR1 to the second main robot CR2. FIG. 3 illustratively shows the positions of the first main robot CR1 and the second main robot CR2 which move toward the second substrate placement portion 11.

The second substrate placement portion 11 is arranged at such a position that a central part thereof substantially overlaps with the transfer-region center line L to L when viewed from above (refer to FIG. 1).

The door 12 provided at the second partition wall 6 is a one-way door that opens in a direction from the third substrate transfer region G3 to the second substrate transfer region G2 but does not open in a direction from the second substrate transfer region G2 to the third substrate transfer region G3.

In the vicinity of the door 12 of the second partition wall 6, there is provided an interlock switch IN1 for cutting off power supplies of the substrate transfer robots (the first main robot CR1 and the second main robot CR2) positioned at substrate transfer regions (that is, the second substrate transfer region G2 and the third substrate transfer region G3) corresponding to the door 12 interlocking with opening of the door 12.

Again, with reference to FIG. 1, there are formed a plurality of openings 15, 16, 17 on the outer wall 2 of the substrate processing apparatus 1. The openings 15 and 16 are respectively provided with doors 18, 19 (first doors) for opening and closing each of the openings 15 and 16, and the opening 17 is provided with a door 20 (a second door) for opening and closing the opening 17.

An operator is able to enter into the inner region of the substrate processing apparatus 1 through the openings 15, 16, 17 and perform maintenance work on the processing units 3, and the robots IR, CR1, CR2. The maintenance work includes teaching (teaching motions), etc., of the individual robots IR, CR1 and CR2.

Interlock switches IN3, IN4 for cutting off a power supply of the substrate transfer robot (indexer robot IR) positioned at the substrate transfer region corresponding to the doors 18, 19 (that is, the first substrate transfer region G1) interlocking with opening of the doors 18, 19 are disposed on the outer wall 2 close to the openings 15, 16. The terminal panel TE1 for coupling a cable (controller cable 21a) of a detachable controller 21 which will be described later is also disposed on the outer wall 2 in the vicinity of the opening 15.

An interlock switch IN5 for cutting off a power supply of the substrate transfer robot (the second main robot CR2) positioned at a substrate transfer region corresponding to the door 20 (that is, the third substrate transfer region G3) interlocking with opening of the door 20 is disposed on the outer wall 2 close to the opening 17. The terminal panel TE2 for coupling a cable (controller cable 21a) of a detachable controller 21 which will be described later is also disposed on the outer wall 2 in the vicinity of the opening 17.

The indexer robot IR is a substrate transfer robot which is provided with a pair of upper and lower hands 22a, 22b, the tip of which is formed in a fork shape, for example, (refer to FIG. 2) , an expanding/contracting mechanism 23 which allows each of the hands 22a and 22b to move back and forth individually to a desired position and an elevating/rotating movement mechanism 24 which allows the expanding/contracting mechanism 23 to move up and down and move rotationally. The indexer robot IR is able to take out a substrate W one at a time from any given cassette 4 by using the lower hand 22b and transfer the taken-out substrate W to the first substrate placement portion 7. The indexer robot IR is also able to receive, by using the upper hand 22a, the substrate W which has been placed on the first substrate placement portion 7 after being processed by the processing unit 3 and transfer the substrate W to the cassette 4 from which the substrate W has been taken out or to any given cassette 4 so that the substrate W can be housed therein.

FIG. 1 shows the indexer robot IR which is positioned at an origin position. That is, the elevating/rotating movement mechanism 24 is positioned substantially at the central position in the arrangement of the plurality of cassettes 4 in the Y direction, and the expanding/contracting mechanism 23 is kept shortest in length. The elevating/rotating movement mechanism 24 is also positioned at such a height that the hands 22a and 22b are substantially equal in height to the first substrate placement portion 7.

The first main robot CR1 is a substrate transfer robot which is provided with a pair of upper and lower hands 25a, 25b, the tip of which is formed in a fork shape, for example, (refer to FIG. 2 and FIG. 3), an expanding/contracting mechanism 26 which allows each of the hands 25a, 25b to move back and forth individually to a desired position, amain body 27 which retains the expanding/contracting mechanism 26, and an elevating/lowering mechanism 28 which is coupled to the main body 27 and which positions each of the hands 25a, 25b to a desired height by allowing the main body 27 to move up and down.

FIG. 1 shows the first main robot CR1 which is positioned at the origin position. That is, the main body 27 is positioned at such a height that the hands 25a and 25b are substantially equal in height to the first substrate placement portion 7. Further, the expanding/contracting mechanism 26 is kept shortest in length so that the hands 25a and 25b are as a whole positioned on the main body 27.

The first main robot CR1 is able to take out a substrate W one at a time from the first substrate placement portion 7 by using the lower hand 25b and transfer the taken-out substrate W to a processing unit 3 at the processing region A, a processing unit 3 at the processing region D, and the second substrate placement portion 11. The first main robot CR1 is also able to receive, by using the upper hand 25a, a substrate W placed at the first substrate placement portion 7 by the second main robot CR2, a substrate W processed by the processing unit 3 at the processing region A and a substrate W processed by the processing unit 3 at the processing region D and transfer them to the first substrate placement portion 7 for placement.

The second main robot CR2 is a substrate transfer robot which is provided with a pair of upper and lower hands 30a, 30b, the tip of which is formed in a fork shape, for example, (refer to FIG. 3) , an expanding/contracting mechanism 31 which allows each of the hands 30a, 30b to move back and forth individually to a desired position, a main body 32 which retains the expanding/contracting mechanism 31, and an elevating/lowering mechanism 33 which is coupled to the main body 32 and which positions the hands 30a, 30b to a desired height by allowing the main body 32 to move up and down.

FIG. 1 shows the second main robot CR2 which is positioned at the origin position. The main body 32 is positioned at such a height that the hands 30a and 30b are substantially equal in height to the second substrate placement portion 11. Further, the expanding/contracting mechanism 31 is kept shortest in length so that the hands 30a and 30b are as a whole positioned on the main body 32.

The second main robot CR2 is able to take out a substrate W one at a time from the second substrate placement portion 11 by using the lower hand 30b and transfer the taken-out substrate W to a processing unit 3 at the processing region B, a processing unit 3 at the processing region C, a processing unit 3 at the processing region E, and a processing unit 3 at the processing region F. The second main robot CR2 is also able to receive by using the upper hand 30a the substrates W processed by the processing units 3 and transfer them to the second substrate placement portion 11 for placement.

In the substrate processing apparatus 1, when teaching the indexer robot IR, the first main robot CR1 and the second main robot CR2, an operator opens any one of the doors 18, 19 and 20 formed on the outer wall 2 and enters into the substrate processing apparatus 1 from any of the openings 15, 16 and 17.

Teaching on substrate delivery motions between the first main robot CR1 and the first substrate placement portion 7 (hereinafter, referred to as CR1/PASS1 teaching) is performed as follows. First, an operator opens the door 18 or 19 and enters into the first substrate transfer region G1 from the opening 15 or 16. Next, the operator moves to a first work position 35 which is set at a position facing the first substrate placement portion 7 of the first substrate transfer region G1 and operates the controller 21 at the position 35 to carry out teaching of the first main robot CR1.

The first work position 35 is a position which directly faces the first substrate placement portion 7 on the side of the first substrate transfer region G1 and is set at such a position that does not interfere with the indexer robot IR positioned at the origin position. The first work position 35 is also set at a position at which an operator can reach, irrespective of whether the operator enters from the door 18 or the door 19 in the first substrate transfer region G1.

Teaching on substrate delivery motions between the indexer robot IR and the first substrate placement portion 7 (hereinafter, referred to as IR/PASS1 teaching) is performed as follows. First, an operator opens the door 20 and enters into the third substrate transfer region G3 from the opening 17, with the controller 21 held. Next, the operator opens the door 12 of the second partition wall 6 and enters into the second substrate transfer region G2 through the opening 42. Thereafter, the operator moves to a second work position 36 which is set at a position facing the first substrate placement portion 7 of the second substrate transfer region G2 to carry out teaching of the indexer robot IR at this position 36 by operating the controller 21.

The second work position 36 is a position which directly faces the first substrate placement portion 7 on the side of the second substrate transfer region G2 and is set at such a position that does not interfere with the first main robot CR1 positioned at the origin position. The second work position 36 is set at such a position that it is at least reachable for an operator who enters into the second substrate transfer region G2 from the door 12.

The first work position 35 and the second work position 36 are each set at a position which deviates in the Y direction from the transfer-region center line L to L, when viewed from above.

Teaching on substrate delivery motions between the second main robot CR2 and the second substrate placement portion 11 (hereinafter, referred to as CR2/PASS2 teaching) is performed as follows. First, an operator opens the door 18 or the door 19 and enters into the first substrate transfer region G1 from the opening 15 or the opening 16, with the controller 21 held. Next, the operator opens the door 8 of the first partition wall 5 and enters into the second substrate transfer region G2 from the opening 41. Thereafter, the operator moves to a third work position 37 which is set at a position facing the second substrate placement portion 11 of the second substrate transfer region G2 and carries out teaching of the second main robot CR2 at this position by operating the controller 21.

The third work position 37 is a position which directly faces the second substrate placement portion 11 on the side of the second substrate transfer region G2 and is set at such a position that does not interfere with the first main robot CR1 positioned at the origin position. The third work position 37 is also set at such a position that it is at least reachable for an operator who enters into the second substrate transfer region G2 from the door 8.

Teaching on substrate delivery motions between the first main robot CR1 and the second substrate placement portion (hereinafter, referred to as CR1/PASS2 teaching) is performed as follows. First, an operator opens the door 20 and enters into the third substrate transfer region G3 from the opening 17, with the controller 21 held. Thereafter, the operator moves to a fourth work position 38 which is set at a position facing the second substrate placement portion 11 of the third substrate transfer region G3 and carries out teaching of the first main robot CR1 at this position by operating the controller 21.

The fourth work position 38 is a position which directly faces the second substrate placement portion 11 on the side of the third substrate transfer region G3 and is set at such a portion that does not interfere with the second main robot CR2 positioned at the origin position. Further, the fourth work position 38 is set at a position that it is at least reachable for an operator who enters into the third substrate transfer region G3 from the door 20.

The third and fourth work positions 37 and 38 are each set at a position at which the center thereof substantially overlaps with the transfer-region center line L to L, when viewed from above.

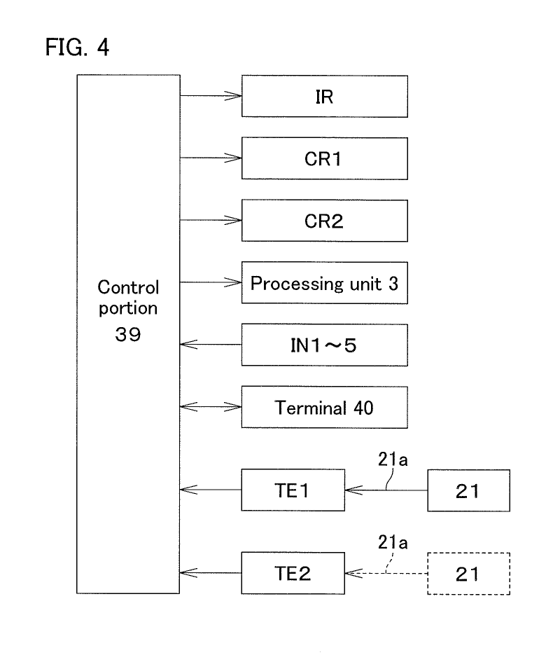

FIG. 4 is a block diagram which illustrates an electrical configuration of the main portion of the substrate processing apparatus 1. A control portion 39 is provided with a microcomputer, thereby controlling a control target which is disposed at the substrate processing apparatus 1 according to predetermined control programs. Specifically, the microcomputer is provided with a CPU (Central Processing Unit) and a memory, and the control programs stored in the memory are carried out by the CPU. The control portion 39 is connected to the indexer robot IR, the first main robot CR1, the second main robot CR2 and a plurality of processing units 3, thereby controlling the motions thereof.

The control portion 39 is also connected to interlock switches IN1 to IN5 and receives input from the interlock switches IN1 to IN5, thereby carrying out interlock motions with regard to the substrate transfer regions G1 to G3 corresponding to each of the interlock switches IN1 to IN5. Specifically, when the interlock switch IN1 is actuated, the control portion 39 turns off the indexer robot IR positioned at the first substrate transfer region G1 and the first main robot CR1 positioned at the second substrate transfer region G2. Further, when the interlock switch IN2 is actuated, the control portion 39 turns off the first main robot CR1 positioned at the second substrate transfer region G2 and the second main robot CR2 positioned at the third substrate transfer region G3. When at least one of the interlock switches IN3 and IN4 is actuated, the control portion 39 turns off the indexer robot IR positioned at the first substrate transfer region G1. When the interlock switch IN5 is actuated, the control portion 39 turns off the second main robot CR2 positioned at the third substrate transfer region G3.

A terminal 40 which is constituted with a commercially available computer, for example, is connected to the control portion 39. An operator is able to check a state, etc., of a substrate W processed in the substrate processing apparatus 1 by the terminal 40. The operator is also able to change the substrate processing apparatus 1 from an ordinary motion state to an idle state by operating operation portions such as a keyboard and a mouse attached to the terminal 40. In the idle state, each of motion portions of the substrate processing apparatus 1, for example, the indexer robot IR, the first main robot CR1, the second main robot CR2 and the processing unit 3 is kept turned off.

The terminal panel TE1 or TE2 is connected to the control portion 39. An operator is able to connect the detachable controller 21 to the control portion 39 via either of the terminal panels TE1 and TE2. The controller 21 may be constituted with a commercially available computer, for example. The operator operates the operation portions such as a keyboard and a mouse attached to the controller 21, thereby inputting into the control portion 39 adjustment signals for adjusting motions of the indexer robot IR, the first main robot CR1 and the second main robot CR2 from the controller 21. It is, thereby, possible to carry out setting of motions (teaching) of each of the robots IR, CR1 and CR2.

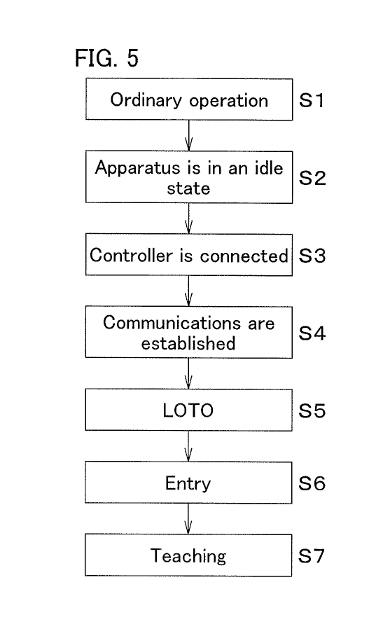

FIG. 5 is a flowchart which illustrates procedures for teaching by an operator.

A description will be started from a state in which the substrate processing apparatus 1 is ordinarily operated (Step S1). In this state, the substrate processing apparatus 1 exhibits interlock functions as usual. Therefore, when the door 18 or the door 19 is opened, the control portion 39 immediately turns off the indexer robot IR, and when the door 20 is opened, the control portion 39 immediately turns off the second main robot CR2.

When the teaching motions are started from the ordinary motion state, an operator inputs teaching start instructions from the terminal 40 (Step S2). Next, the control portion 39 changes the substrate processing apparatus 1 to the idle state. Thereby, all movable elements inside the substrate processing apparatus 1 are turned off. Specifically, all the processing units 3, the indexer robot IR, the first main robot CR1 and the second main robot CR2 are turned off. On the other hand, interlock functions are kept on the basis of actuation of the interlock switches IN1 to INS.

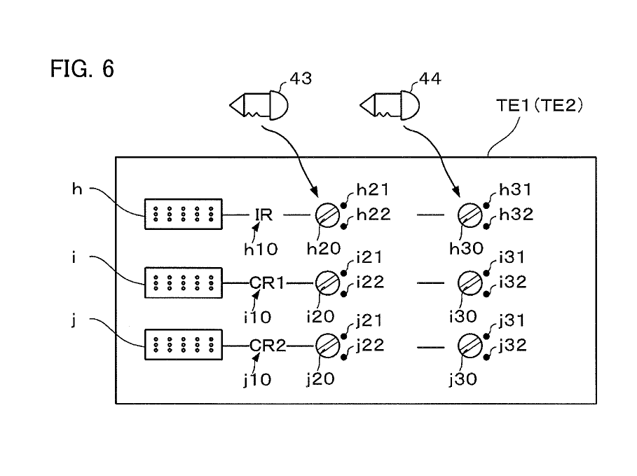

Next, a cable (controller cable 21a) attached to the controller 21 is coupled to the terminal panel TE1 or the terminal panel TE2 (Step S3). FIG. 6 is a plan view of the terminal panel TE1 (terminal panel TE2). The terminal panel TE1 and the terminal panel TE2 are of the same type. The terminal panel TE1 has cable terminals h, i and j. The cable terminals h, i, j are respective cable terminals for connecting the controller cable 21a when teaching the indexer robot IR, the first main robot CR1 and the second main robot CR2. Reference signs h10, i10 and j10 are provided on the terminal panel TE1 (TE2) for indicating that the cable terminals h, i and j correspond respectively to the robots IR, CR1 and CR2.

A first keyhole h20 is a keyhole for inserting a robot connecting key 43. An operator connects the controller cable 21a (not shown in FIG. 5) to the cable terminal h of the cable terminal panel TE1 or TE2 and, thereafter, inserts the robot connecting key 43 into the first keyhole h20 corresponding to the indexer robot IR, thereby rotating the key 43 between two switching positions h21 and h22. Thereby, signals transmitted between the controller 21 and the control portion 39 can be made into a cut-off state (when the first keyhole h20 is at the switching position h21) or a communication state (when the first keyhole h20 is at the switching position h22). When the operator rotates the robot connecting key 43 at the switching position h22 (Step S4, communications established), the control portion 39 returns only the indexer robot IR from a turned-off state to a turned-on state. At this time, the first and the second main robot, CR1 and CR2 are kept turned off.

In the above-described case, the first keyhole h20 and the control portion 39 turn on only the indexer robot IR, while keeping the first and the second main robot CR1, CR2 turned off. Therefore, the first keyhole h20 and the control portion 39 correspond to a selective power supply turn-on means of the indexer robot IR.

Similarly, an operator connects the controller cable 21a (not shown in FIG. 5) to the cable terminal i of the cable terminal panel TE1 or TE2 and, thereafter, inserts the robot connecting key 43 into the first keyhole i20 corresponding to the first main robot CR1, thereby rotating the key 44 between two switching positions i21 and i22. Thereby, signals transmitted between the cable terminal i and the control portion 39 can be made into a cut-off state (when the first keyhole i20 is at the switching position i21) or a communication state (when the first keyhole i20 is at the switching position i22). When the operator rotates the key 43 at the switching position i22 (Step S4, communications established) , the control portion 39 turns only the first main robot CR1 from a turned-off state to a turned-on state. At this time, the indexer robot IR and the second main robot CR2 are kept turned off.

In the above-described case, the first keyhole i20 and the control portion 39 keep only the first main robot CR1 turned on, while keeping the indexer robot IR and the second main robot CR2 turned off. Therefore, the first keyhole i20 and the control portion 39 correspond to a selective power supply turn-on means of the first main robot CR1.

Similarly, an operator connects the controller cable 21a (not shown in FIG. 5) to the cable terminal j of the terminal panel TE1 (TE2) and, thereafter, inserts the robot connecting key 43 into the first keyhole j20 corresponding to the second main robot CR2, thereby rotating the key 43 between two switching positions j21 and j22. Thereby, signals transmitted between the cable terminal j and the control portion 39 can be made into a cut-off state (when the first keyhole j20 is at the switching position j21) ora communication state (when the first keyhole j20 is at the switching position j22). When the operator rotates the key 43 at the switching position j22 (Step S4, communications established), the control portion 39 returns only the second main robot CR2 from a turned-off state to a turned-on state. At this time, the indexer robot IR and the first main robot CR1 are kept turned off.

In the above-described case, the first keyhole j20 and the control portion 39 turns on only the second main robot CR2, while keeping the indexer robot IR and the first main robot CR1 turned off. Therefore, the first keyhole j20 and the control portion 39 correspond to a selective power supply turn-on means of the second main robot CR2.

The substrate processing apparatus 1 has two terminal panels TE1 and TE2. An operator is able to connect the controller cable 21a to either of the terminal panel TE1 and the terminal panel TE2. However, when a communication state is established between one of the terminal panels (for example, TE1) and the control portion 39, the other terminal panel (for example, TE2) becomes invalid. Therefore, even if the operator connects another controller cable 21a to the other terminal panel (for example, TE2), no signal communications can be established between the controller 21 and the control portion 39.

A second keyhole h30 is a keyhole for inserting an interlock suspending key 44. The second keyhole h30 has switching positions h31 and h32. When the second keyhole h30 is positioned at the switching position h31, interlock functions are retained at a substrate transfer region corresponding to the second keyhole h30 (the first substrate transfer region G1). On the other hand, when the second keyhole h30 rotates at the switching position h32, interlock functions are partially released at the substrate transfer region corresponding to the second keyhole h30 (the first substrate transfer region G1). That is, even if the door 8 is opened in a state that interlock functions of the first substrate transfer region G1 are turned on, the indexer robot IR can be prevented from being turned off. On the other hand, interlock functions are retained continuously at the door 18 and the door 19. This is an exceptional case in which work efficiency of teaching is taken into account.

A second keyhole i30 is also a keyhole for inserting the interlock suspending key 44. When the second keyhole i30 is rotated from a switching position i31 to a switching position i32, interlock functions are switched off at the door 8 and the door 12 which close the opening 41 and the opening 42 leading to the substrate transfer region G2 which corresponds to the first main robot CR1.

Similarly, a second keyhole j30 is also a keyhole for inserting the interlock suspending key 44. When the second keyhole j30 is rotated from a switching position j31 to a switching position j32, interlock functions are switched off at the door 12 which closes the opening 42 leading to the substrate transfer region G3 which corresponds to the second main robot CR2. On the other hand, interlock functions are retained at the door 20.

Again, with reference to the flowchart of FIG. 5, an operator carries out “the controller is connected” in Step S3 and “communications are established” in Step S4, by which a teaching target is designated for the control portion 39.

Next, an operator carries out LOTO (Lock Out Tag Out) (Step S5). That is, a power switch (not shown) disposed on the outer wall 2 of the substrate processing apparatus 1 is locked to disable the apparatus from being operated by a person other than the operator, and a tag is also attached on the outer wall 2 to carry out work for indicating to persons outside the substrate processing apparatus 1 that the substrate processing apparatus 1 is engaged in teaching work.

Next, the operator opens any of the doors 8, 12, and 18 to 20 which are to be used upon the teaching work and enters into the substrate processing apparatus 1 (Step S6).

The doors 18 and 19 correspond to “CR1/PASS1 teaching.” When the “CR1/PASS1 teaching” is carried out, an operator opens either of the door 18 or the door 19 and enters into the first substrate transfer region G1.

The door 20 and the door 12 correspond to “IR/PASS1 teaching.” When the “IR/PASS1 teaching” is carried out, an operator opens the door 20 and the door 12 and enters into the second substrate transfer region G2 via the third substrate transfer region G3.

The door 18, the door 19 and the door 8 correspond to “CR2/PASS2 teaching.” When the “CR1/PASS2 teaching” is carried out, an operator opens the door 18 or the door 19 and the door 8 and enters into the second substrate transfer region G2 via the first substrate transfer region G1.

The door 20 is to be used upon “CR1/PASS2 teaching.” When the “CR2/PASS2 teaching” is carried out, an operator opens the door 20 and enters into the third substrate transfer region G3.

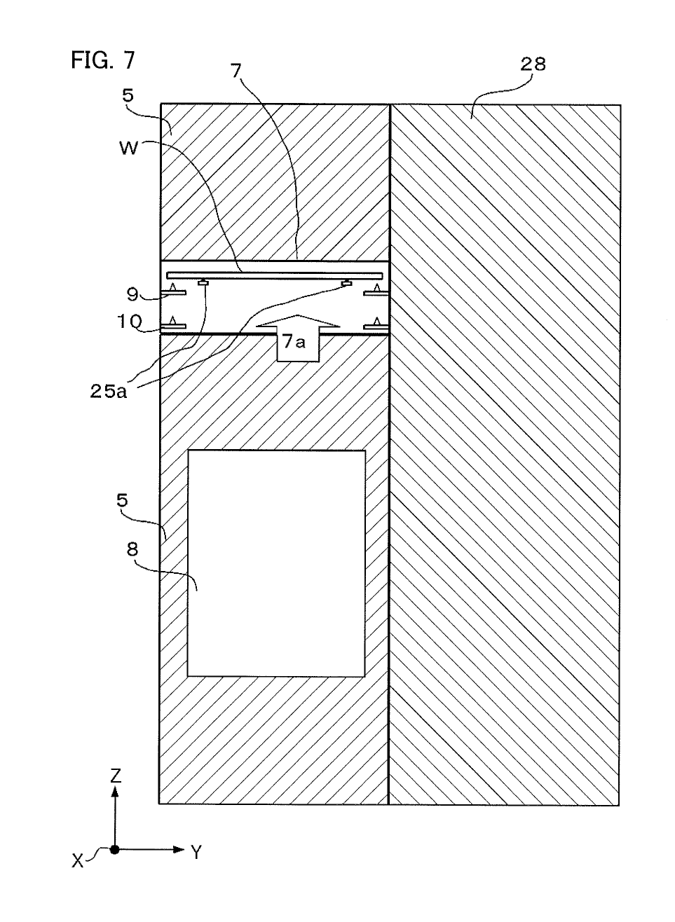

FIG. 7 is a front elevational view of the first partition wall 5 when viewed from the first work position 35. An operator positioned at the first work position 35 is able to observe macroscopically conditions of the first main robot CR1 located at the second substrate transfer region G2 from an internal space of the first substrate placement portion 7 (referred to as a first observation region 7a). In FIG. 7, slanting lines are given for clarification to parts excluding the first observation region 7a and the door 8, specifically, the first partition wall 5 and the elevating/lowering mechanism 28.

FIG. 7 shows a situation in which the upper hand 25a of the first main robot CR1 supports a substrate W immediately above an upper substrate supporting member 9 in the first observation region 7a. The hand 25a is able to deliver the supported substrate W to the substrate supporting member 9 by moving down from a state shown in FIG. 7.

Although not shown in the drawing, contrary to the above situation, the lower hand 25b scoops up a substrate W retained by a substrate supporting member 10 from below, thus making it possible to deliver the substrate W from the substrate supporting member 10 to the lower hand 25b. Work for adjusting these delivery motions is collectively referred to as “CR1/PASS1 teaching.”

An operator is able to adjust motions of the hands 25 by operating the controller from the first work position 35 and carry out “CR1/PASS1 teaching.” As a result of the “CR1/PASS1 teaching,” the upper hand 25a is able to place accurately a substrate W on the substrate supporting member 9, and the lower hand 25b is able to scoop up a substrate W accurately from the substrate supporting member 10.

An operator positioned at the first work position 35 is isolated from the first main robot CR1 by the first partition wall 5 and the elevating/lowering mechanism 28. Therefore, the operator is able to work safely. An interlock is also set at the second substrate transfer region G2.

Therefore, even if the door 8 or the door 12 is opened, the first main robot CR1 is turned off to stop motions safely.

When “IR/PASS1 teaching” is carried out, an operator is positioned at the second work position 36 to perform the work, directly facing the first partition wall 5. At this time, a structure visible to the operator is mirror-symmetric to the structure of FIG. 7. The operator performs teaching while observing macroscopically motions of the hands 22 of the indexer robot IR through the first observation region 7a. The operator is isolated from the indexer robot IR by the first partition wall 5 and the elevating/lowering mechanism 28 and, therefore, able to conduct the work safely. Further, the door 8 is a one-way door that opens in a direction from the first substrate transfer region G1 to the second substrate transfer region G2, thereby decreasing a risk that the operator may enter from the side of the second substrate transfer region G2 to the first substrate transfer region G1. Still further, if the door 18 or 19 is opened by a person other than the operator, the interlock is immediately actuated to turn off the indexer robot IR.

The operator is able to carry out “IR/PASS1 teaching” by operating the controller to adjust motions of the hands 22 of the indexer robot IR. As a result of the “IR/PASS1 teaching,” the upper hand 22a is able to accurately place a substrate W on the substrate supporting member 9, and the lower hand 22b is able to accurately scoop up a substrate W from the substrate supporting member 10.

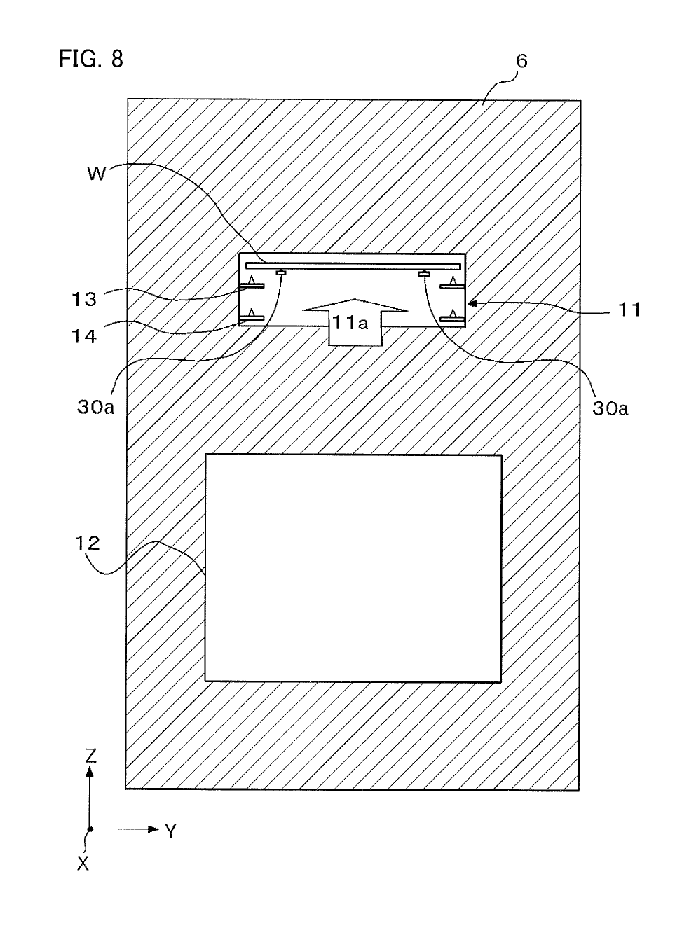

FIG. 8 is a front elevational view of the second partition wall 6 when viewed from the third work position 37. An operator positioned at the third work position 37 is able to observe macroscopically conditions of the second main robot CR2 at the third substrate transfer region G3 through an internal space of a second substrate placement portion 11 (referred to as a second observation region 11a). In FIG. 8, slanting lines are given for clarification to a part excluding the second observation region 11a and the door 12, specifically, the second partition wall 6.

FIG. 8 shows a situation in which the upper hand 30a of the second main robot CR2 supports a substrate W immediately above an upper substrate supporting member 13 in the first observation region 7a. The upper hand 30a is able to deliver the supported substrate W to the substrate supporting member 13 by moving down from a state shown in FIG. 8.

Although not shown in the drawing, contrary to the above situation, the lower hand 30b scoops up a substrate W retained by a substrate supporting member 14 from below, thus making it possible to deliver the substrate W from the substrate supporting member 14 to the lower hand 30b. Work of adjusting the delivery motions is collectively referred to as “CR2/PASS2 teaching.”

An operator is able to operate the controller 21 while observing macroscopically the hands 30 to adjust motions of the hands 30 and thereby carry out “CR2/PASS2 teaching.” As a result of the “CR2/PASS2 teaching,” the upper hand 30a is able to place accurately a substrate W on the substrate supporting member 13, and the lower hand 30b is able to scoop up a substrate W accurately from the substrate supporting member 14.

An operator is isolated from the second main robot

CR2 by the second partition wall 6 and, therefore, able to work safely. Further, the door 12 is a one-way door that does not open in a direction from the second substrate transfer region G2 to the third substrate transfer region G3, thereby decreasing a risk that the operator may enter into the third substrate transfer region G3 from the second substrate transfer region G2.

Further, interlock functions are set at the third substrate transfer region G3. Therefore, even if the door 12 or the door 20 is opened, the second main robot CR2 is turned off to stop motions thereof safely.

When “CR1/PASS2 teaching” is carried out, an operator is positioned at the fourth work position 38 to work directly facing the second partition wall 6. At this time, a structure visible to the operator is mirror-symmetrical to the structure of FIG. 8. The operator performs teaching, while observing macroscopically motions of the hands 25 of the first main robot CR1 through the second observation region 11a. The operator is isolated from the first main robot CR1 by the second partition wall 6 and is, therefore, able to work safely.

Further, if the door 8 is opened by a person other than the operator, the interlock is immediately actuated to turn off the first main robot CR1.

An operator is able to carry out “CR1/PASS2 teaching” by operating the controller to adjust motions of the hands 25 of the first main robot CR1. As a result of the “CR1/PASS2 teaching,” the upper hand 25a is able to place accurately a substrate Won the substrate supporting member 13, and the lower hand 25b is able to scoop up a substrate W accurately from the substrate supporting member 14.

Although a description has been so far given of the preferred embodiments of the present invention, the present invention can also be carried out in other modes. For example, in the above-described preferred embodiments, the first observation region 7a is disposed inside the first substrate placement portion 7. However, a position of the first observation region is not limited thereto. For example, a transparent region which is different from the first substrate placement portion 7 may be formed at the first partition wall 5 and given as a first observation region. Through the transparent region, motions of the first main robot CR1 and motions of the indexer robot IR may be macroscopically observed respectively from the first substrate transfer region G1 and from the second substrate transfer region G2.

Similarly, in the above-described preferred embodiment, the second observation region 11a is disposed inside the second substrate placement portion 11. However, a position of the second observation region is not limited thereto. For example, a transparent region which is different from the second substrate placement portion 11 may be formed at the second partition wall 6 and given as a second observation region. Through the transparent region, motions of the second main robot CR2 and motions of the first main robot CR1 may be macroscopically observed respectively from the second substrate transfer region G2 and from the third substrate transfer region G3.

In the above-described preferred embodiment, the door 12 is made into a one-way door, thereby preventing an operator who conducts “CR2/PASS2 teaching” from erroneously entering into the third substrate transfer region G3 from the second substrate transfer region G2. Alternatively, sensors, etc., may be used to detect the fact that the door 18 or the door 19 is opened and also the door 8 is opened, and, in response, the door 12 may be locked.

In the above-described preferred embodiment, the door 8 is also made into a one-way door, thereby preventing an operator who conducts “IR/PASS1 teaching” from erroneously entering into the first substrate transfer region G1 from the second substrate transfer region G2. Alternatively, sensors may be used to detect the fact that the door 20 and the door 12 are opened, and, in response, the door 8 may be locked.

In the above-described preferred embodiment, such a case that teaching work is carried out with respect to the substrate processing apparatus 1 in an ordinary operating state, is used as an example. In this case, prior to start of the teaching, a substrate transfer region at which a robot other than a teaching target robot is positioned is at first turned off (refer to Step S2 in FIG. 5).

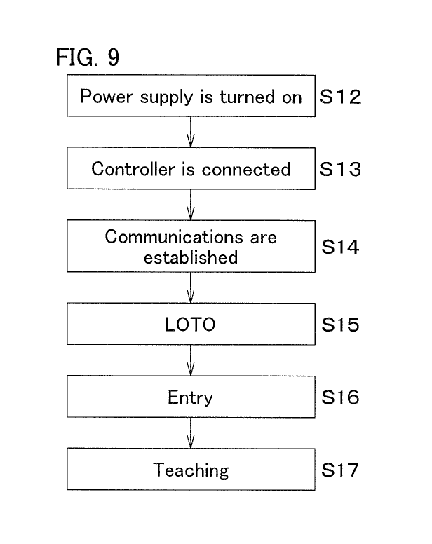

However, it is also possible to carry out the teaching work with respect to the substrate processing apparatus 1 in a turned-off state. Procedures for this case will be described by using the flowchart of FIG. 9.

First, an operator activates the substrate processing apparatus 1 from the terminal 40 (Step S12). Thereby, interlock functions of the interlock switches IN1 to

IN5 of the substrate processing apparatus 1 are activated. Next, the operator selects a cable terminal corresponding to a teaching target robot from the plurality of cable terminals h, i, j of the terminal panel TE and connects the selected cable terminal to the controller cable 21a (Step S13). Next, the operator rotates first keyholes h20, i20, j20 of the cable terminals h, i, j to which the controller cable 21a is connected, thereby establishing communications between the teaching target robot and the control portion 39 (Step S14). Thereby, the control portion 39 turns on the teaching target robot, keeping other robots turned off. Accordingly, the first keyholes h20, i20, j20 and the control portion 39 correspond to a selective power supply turn-on means of the substrate transfer robot.

Subsequent Steps S15 to S17 are the same as Steps S5 to S7 in FIG. 5 which have been described previously, and a description thereof will be omitted here.

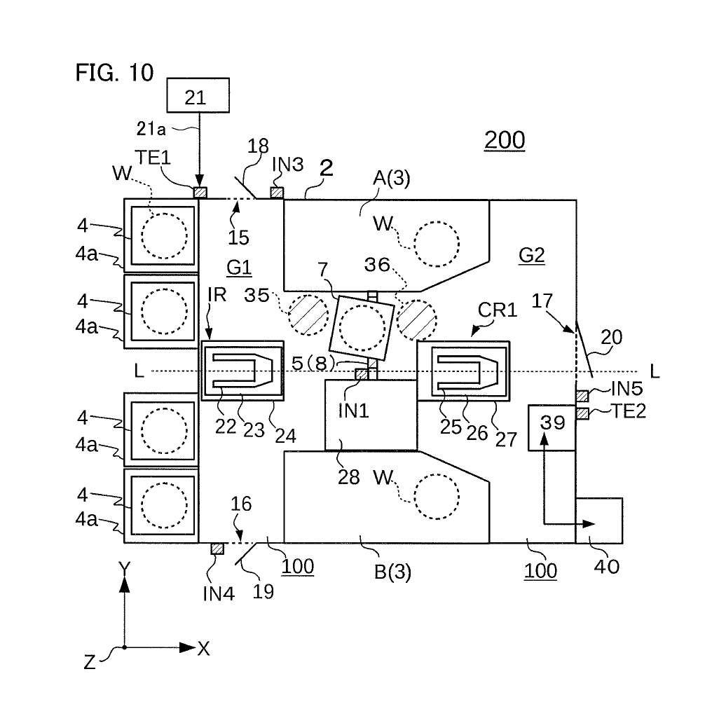

FIG. 10 is a plan view which shows a substrate processing apparatus 200 according to a second preferred embodiment. The substrate processing apparatus 200 is different from the substrate processing apparatus 1 of the first preferred embodiment in that it does not have a third substrate transfer region G3, a second main robot CR2, processing regions C, D, E, F or a second partition wall 6. Further, a door 20 (second door) is disposed on an outer wall 2 and leads to a second substrate transfer region G2. The substrate processing apparatus 200 is substantially similar in the other points to the substrate processing apparatus 1 of the first preferred embodiment.

An inner region 100 of the substrate processing apparatus 200 is surrounded by the outer wall 2. The inner region 100 is divided by a first partition wall 5 into a first substrate transfer region G1 and the second substrate transfer region G2. An indexer robot IR is disposed at the first substrate transfer region G1. A first main robot CR1 is disposed at the second substrate transfer region G2. Processing units 3 at processing regions A and B are disposed adjacent on both sides of the second substrate transfer region G2 along the X direction.

The plurality of processing units 3 (4 units in the present preferred embodiment) for conducting specific processing such as cleaning and etching are stacked in a vertical direction (Z direction) in the processing regions A and B.

The indexer robot IR delivers a substrate W to the first main robot CR1 via a first substrate placement portion 7. The first main robot CR1 delivers a substrate W to the indexer robot IR via the first substrate placement portion 7 and also delivers a substrate W between the processing units 3 at the processing regions A and B.

Motions of the indexer robot IR and those of the first main robot CR1 are controlled by a control portion 39.

IR/PASS1 teaching and CR1/PASS1 teaching can be carried out in the substrate processing apparatus 200.

When the IR/PASS1 teaching is carried out, an operator makes the substrate processing apparatus 200 into an idle state (Step S2 in FIG. 5) and also connects a controller 21 to a terminal panel TE1 or TE2 via a controller cable 21a (S3 in FIG. 5). Thereafter, the operator rotates a first keyhole h20 corresponding to the indexer robot IR to a switching position h22, thereby establishing communications between the controller 21 and a control portion 39 (S4 in FIG. 5). At this time, the control portion 39 makes only the indexer robot IR into a turned-on state from a turned-off state. At this time, the first main robot CR1 is kept in a turned-off state.

Next, the operator carries out LOTO (S5 in FIG. 5).

Next, the operator opens a door 20 and enters into the second substrate transfer region G2 from an opening 17, with the controller 21 held, and moves to a second work position 36 (S6 in FIG. 5). The operator observes macroscopically motions of the indexer robot IR inside the first substrate transfer region G1 through a first observation region 7a (refer to FIG. 7) disposed inside a first substrate placement portion 7 of the first partition wall 5 from a second work position 36 and also operates the controller 21 to adjust motions of hands 22 of the indexer robot IR (S7 in FIG. 5). The controller 21 inputs an adjustment signal to the control portion 39 to carry out IR/PASS1 teaching.

When CR1/PASS1 teaching is carried out, an operator makes the substrate processing apparatus 200 into an idle state (Step S2 in FIG. 5) and connects the controller 21 to the terminal panel TE1 or TE2 via the controller cable 21a (S3 in FIG. 5). Thereafter, the operator rotates a first keyhole i20 corresponding to the first main robot CR1 to a switching position i22, thereby establishing communications between the controller 21 and the control portion 39 (S4 in FIG. 5). At this time, the control portion 39 makes only the first main robot CR1 into a turned-on state from a turned-off state. At this time, the indexer robot IR is kept in a turned-off state.

Next, the operator carries out LOTO (S5 in FIG. 5).

Next, the operator opens a door 18 or 19 (first door) and enters into the first substrate transfer region G1 from an opening 15 or 16, with the controller 21 held, and moves to a first work position 35 (S6 in FIG. 5). The operator observes macroscopically motions of the first main robot CR1 inside the second substrate transfer region G2 through the first observation region 7a (refer to FIG. 7) disposed inside the first substrate placement portion 7 of the first partition wall 5 from the first work position 35 and also operates the controller 21 to adjust motions of hands 25 of the first main robot CR1 (S7 in FIG. 5). The controller 21 inputs an adjustment signal to the control portion 39 to carry out CR1/PASS1 teaching.

While preferred embodiments of the present invention have been described in detail above, these are merely specific examples used to clarify the technical contents of the present invention, and the present invention should not be interpreted as being limited only to these specific examples, and the scope of the present invention shall be limited only by the appended claims.

The present application corresponds to Japanese Patent Application No. 2016-67178 filed in the Japan Patent Office on Mar. 30, 2016, and the entire disclosure of this application is incorporated herein by reference.

### REFERENCE SIGNS LIST

1: Substrate processing apparatus
2: Outer wall
3: Processing unit
4: Cassette
5: First partition wall
6: Second partition wall
7: First substrate placement portion
7a: First observation region
8: Door
9: Substrate supporting member
10: Substrate supporting member
11: Second substrate placement portion
11a: Second observation region
12: Door
13: Substrate supporting member
14: Substrate supporting member
15: Opening
16: Opening
17: Opening
18: Door
19: Door
20: Door
21: Controller
21a: Controller cable
22, 22a, 22b: Hand of IR
23: Expanding/contracting mechanism
24: Elevating/rotating movement mechanism
25, 25a, 25b: Hand of CR1
f26: Expanding/contracting mechanism
27: Main body
28: Elevating/lowering mechanism
30, 30a, 30b: Hand of CR2
31: Expanding/contracting mechanism
32: Main body
33: Elevating/lowering mechanism
35: First work position
36: Second work position
37: Third work position
38: Fourth work position
39: Control portion
40: Terminal
A: Processing region
B: Processing region
C: Processing region
D: Processing region
E: Processing region
F: Processing region
G: Transfer region
G1: First transfer region
G2: Second transfer region
G3: Third transfer region
IR: Indexer robot
CR1: First main robot
CR2: Second main robot
IN1: Interlock switch
IN2: Interlock switch
IN3: Interlock switch
IN4: Interlock switch
IN5: Interlock switch
TE1: Terminal panel
TE2: Terminal panel
h: Cable terminal
i: Cable terminal
j: Cable terminal
h10: Reference sign
h20: First keyhole
h21: Switching position
h22: Switching position

1-10. (canceled)

11. A substrate processing apparatus which has an inner region surrounded by an outer wall, comprising:
a first partition wall which divides the inner region into first and second substrate transfer regions;
first and second substrate transfer robots which are arranged respectively at the first and second substrate transfer regions;
a processing unit which is disposed adjacent to the second substrate transfer region in order to give predetermined substrate processing to a substrate;
a control portion which controls motions of the first and second substrate transfer robots;
a selective power supply turn-on means which selectively turns on the second substrate transfer robot, while turning off the first substrate transfer robot;
a controller which inputs to the control portion an adjustment signal for adjusting motions of the second substrate transfer robot; and
an interlock means which individually detects an entry of a person into each of the first and second substrate transfer regions and turns off a substrate transfer robot at a corresponding region; wherein
a first observation region for observing macroscopically the second substrate transfer region from the first substrate transfer region is formed at the first partition wall,
a first door which leads to the first substrate transfer region is disposed on the outer wall,
the first substrate transfer robot delivers and receives a substrate to and from the second substrate transfer robot,
the second substrate transfer robot delivers and receives a substrate to and from the first substrate transfer robot and also delivers and receives a substrate to and from the processing unit, and
at the first substrate transfer region, there is set a first work position at which an operator who has reached the first substrate transfer region through the first door observes macroscopically the second substrate transfer robot through the first observation region and adjusts motions of the second substrate transfer robot via the controller.

12. The substrate processing apparatus according to claim 11, wherein a first substrate placement portion for placing a substrate when delivering a substrate between the first substrate transfer robot and the second substrate transfer robot is provided so as to penetrate through the first partition wall, and the first observation region is set inside the first substrate placement portion.

13. A substrate processing apparatus which has an inner region surrounded by an outer wall, comprising:
first and second partition walls which divide the inner region into first, second and third substrate transfer regions;
first, second and third substrate transfer robots which are arranged respectively at the first, the second and third substrate transfer regions:
a processing unit which is disposed adjacent to the third substrate transfer region in order to give predetermined substrate processing to a substrate;
a control portion which controls motions of the first, second and third substrate transfer robots;
a selective power supply turn-on means which selectively turns on the second substrate transfer robot, while turning off the first and the third substrate transfer robot;
a controller which inputs to the control portion an adjustment signal for adjusting motions of the second substrate transfer robot; and
an interlock means which individually detects the entry of a person into each of the first, second and third substrate transfer regions and turns off a substrate transfer robot at a corresponding region; wherein
a first observation region for observing macroscopically the second substrate transfer region from the first substrate transfer region is formed at the first partition wall,
a first door which leads to the first substrate transfer region is disposed on the outer wall,
the first substrate transfer robot delivers and receives a substrate to and from the second substrate transfer robot,
the second substrate transfer robot delivers and receives a substrate to and from the first substrate transfer robot and also delivers and receives a substrate to and from the third substrate transfer robot,
the third substrate transfer robot delivers and receives a substrate to and from the second substrate transfer robot and also delivers and receives a substrate to and from the processing unit, and
at the first substrate transfer region, there is set a first work position at which an operator who has reached the first substrate transfer region through the first door observes macroscopically the second substrate transfer robot through the first observation region and adjusts motions of the second substrate transfer robot via the controller.

14. The substrate processing apparatus according to claim 13, wherein a first substrate placement portion for placing a substrate when delivering a substrate between the first substrate transfer robot and the second substrate transfer robot is provided so as to penetrate through the first partition wall, and the first observation region is set inside the first substrate placement portion.

15. A substrate processing apparatus which has an inner region surrounded by an outer wall, comprising:
a first partition wall which divides the inner region into first and second substrate transfer regions;
first and second substrate transfer robots which are arranged respectively at the first and second substrate transfer regions;
a processing unit which is disposed adjacent to the second substrate transfer region in order to give predetermined substrate processing to a substrate;
a control portion which controls motions of the first and second substrate transfer robots;
a selective power supply turn-on means which selectively turns on the first substrate transfer robot, while turning off the second substrate transfer robot;
a controller which inputs to the control portion an adjustment signal for adjusting motions of the first substrate transfer robot; and
an interlock means which individually detects the entry of a person into each of the first and second substrate transfer regions and turns off a substrate transfer robot at a corresponding region; wherein
a first observation region for observing macroscopically the first substrate transfer region from the second substrate transfer region is formed at the first partition wall,
a second door which leads to the second substrate transfer region is disposed on the outer wall,
the first substrate transfer robot delivers and receives a substrate to and from the second substrate transfer robot,
the second substrate transfer robot delivers and receives a substrate to and from the first substrate transfer robot and also delivers and receives a substrate to and from the processing unit, and
at the second substrate transfer region, there is set a second work position at which an operator who has reached the second substrate transfer region through the second door observes macroscopically the first substrate transfer robot through the first observation region and adjusts motions of the first substrate transfer robot via the controller.

16. The substrate processing apparatus according to claim 15, wherein the first partition wall is provided with a one-way door that opens in a direction from the first substrate transfer region to the second substrate transfer region but does not open in a reverse direction.

17. The substrate processing apparatus according to claim 15, wherein a first substrate placement portion for placing a substrate when delivering a substrate between the first substrate transfer robot and the second substrate transfer robot is provided so as to penetrate through the first partition wall, and the first observation region is set inside the first substrate placement portion.

18. A substrate processing apparatus which has an inner region surrounded by an outer wall, comprising:
first and second partition walls which divide the inner region into first, second and third substrate transfer regions;
first, second and third substrate transfer robots which are arranged respectively at the first, second and third substrate transfer regions;
a processing unit which is disposed adjacent to the third substrate transfer region in order to give predetermined substrate processing to a substrate;
a control portion which controls motions of the first, second and third substrate transfer robots;
a selective power supply turn-on means which selectively turns on the first substrate transfer robot, while turning off the second and third substrate transfer robots;
a controller which inputs to the control portion an adjustment signal for adjusting motions of the first substrate transfer robot; and
an interlock means which individually detects the entry of a person into each of the first to third substrate transfer regions to stop motions of a substrate transfer robot at a corresponding region; wherein
a first observation region for observing macroscopically the first substrate transfer region from the second substrate transfer region is formed at the first partition wall,
a second door which leads to the third substrate transfer region is disposed on the outer wall,
a third door which leads to the second substrate transfer region from the third substrate transfer region is disposed at the second partition wall,
the first substrate transfer robot delivers and receives a substrate to and from the second substrate transfer robot,
the second substrate transfer robot delivers and receives a substrate to and from the third substrate transfer robot,
the third substrate transfer robot delivers and receives a substrate to and from the second substrate transfer robot and also delivers and receives a substrate to and from the processing unit at the third substrate transfer region, and
at the second substrate transfer region, there is set a second work position at which an operator who has reached the second substrate transfer region through the second and third doors observes macroscopically the first substrate transfer robot through the first observation region and adjusts motions of the first substrate transfer robot via the controller.

19. The substrate processing apparatus according to claim 18, wherein the first partition wall is provided with a one-way door that opens in a direction from the first substrate transfer region to the second substrate transfer region but does not open in a reverse direction.

20. The substrate processing apparatus according to claim 18, wherein a first substrate placement portion for placing a substrate when delivering a substrate between the first substrate transfer robot and the second substrate transfer robot is provided so as to penetrate through the first partition wall, and the first observation region is set inside the first substrate placement portion.

21. A substrate processing apparatus which has an inner region surrounded by an outer wall, comprising:
first and second partition walls which divide the inner region into first, second and third substrate transfer regions;
first, second and third substrate transfer robots which are arranged respectively at the first, second and third substrate transfer regions;
a processing unit which is disposed adjacent to the third substrate transfer region in order to give predetermined substrate processing to a substrate;
a control portion which controls motions of the first, second and third substrate transfer robots;
a selective power supply turn-on means which selectively turns on the third substrate transfer robot, while turning off the first and second substrate transfer robots;
a controller which inputs to the control portion an adjustment signal for adjusting motions of the third substrate transfer robot; and
an interlock means which individually detects the entry of a person into each of the first, second and third substrate transfer regions and turns off a substrate transfer robot at a corresponding region; wherein
a second observation region for observing macroscopically the third substrate transfer region from the second substrate transfer region is formed at the second partition wall,
a first door which leads to the first substrate transfer region is disposed on the outer wall,
a fourth door which leads to the second substrate transfer region from the first substrate transfer region is disposed at the first partition wall,
the first substrate transfer robot delivers and receives a substrate to and from the second substrate transfer robot,
the second substrate transfer robot delivers and receives a substrate to and from the first substrate transfer robot and also delivers and receives a substrate to and from the third substrate transfer robot,
the third substrate transfer robot delivers and receives a substrate to and from the second substrate transfer robot and also delivers and receives a substrate to and from the processing unit,
at the second substrate transfer region, there is set a third work position at which an operator who has reached the second substrate transfer region through the first door and the fourth door observes macroscopically the third substrate transfer robot through the second observation region and adjusts motions of the third substrate transfer robot via the controller.

22. The substrate processing apparatus according to claim 21, wherein the second partition wall is provided with a one-way door that opens in a direction from the third substrate transfer region to the second substrate transfer region but does not open in a reverse direction.

23. The substrate processing apparatus according claim 21, wherein a second substrate placement portion for placing a substrate when delivering a substrate between the second substrate transfer robot and the third substrate transfer robot is provided so as to penetrate through the second partition wall, and the second observation region is set inside the second substrate placement portion.

24. A substrate processing apparatus which has an inner region surrounded by an outer wall, comprising:
first and second partition walls which divide the inner region into first, second and third substrate transfer regions;
first, second and third substrate transfer robots which are arranged respectively at the first, second and third substrate transfer regions;
a processing unit which is disposed adjacent to the third substrate transfer region in order to give predetermined substrate processing to a substrate;
a control portion which controls motions of the first, second and third substrate transfer robots,
a selective power supply turn-on means which selectively turns on the second substrate transfer robot, while turning off the first and third substrate transfer robots;
a controller which inputs to the control portion an adjustment signal for adjusting motions of the second substrate transfer robot; and
an interlock means which individually detects the entry of a person into each of the first, second and third substrate transfer regions and turns off a substrate transfer robot at a corresponding region; wherein
a second observation region for observing macroscopically the second substrate transfer region from the third substrate transfer region is formed at the second partition wall,
a second door which leads to the third substrate transfer region is disposed on the outer wall,
the first substrate transfer robot delivers and receives a substrate to and from the second substrate transfer robot,
the second substrate transfer robot delivers and receives a substrate to and from the first substrate transfer robot and also delivers and receives a substrate to and from the third substrate transfer robot,
the third substrate transfer robot delivers and receives a substrate to and from the second substrate transfer robot and also delivers and receives a substrate to and from the processing unit, and
at the third substrate transfer region, there is set a fourth work position at which an operator who has reached the third substrate transfer region through the second door observes macroscopically the second substrate transfer robot through the second observation region and adjusts motions of the second substrate transfer robot via the controller.

25. The substrate processing apparatus according claim 24, wherein a second substrate placement portion for placing a substrate when delivering a substrate between the second substrate transfer robot and the third substrate transfer robot is provided so as to penetrate through the second partition wall, and the second observation region is set inside the second substrate placement portion.
